(19) United States
(12) Patent Application Publication
(10) Pub. No.: US 2026/0271525 A1
(43) Pub. Date: Sep. 10, 2026

(54) DISPLAY DEVICE AND ELECTRONIC DEVICE INCLUDING THE SAME

(71) Applicant: Samsung Display Co., Ltd., Yongin-Si (KR)

(72) Inventors: SUKYO JUNG, Yongin-si (KR); Kwangsoon Park, Yongin-si (KR); MINJOO KIM, Yongin-si (KR); NACKHYEON KEUM, Yongin-si (KR); JEONGHUN BANG, Yongin-si (KR)

(21) Appl. No.: 19/559,063

(22) Filed: Mar. 6, 2026

(30) Foreign Application Priority Data
Mar. 10, 2025 (KR) 10-2025-0030909

(51) Int. Cl. H10K 59/121; H10D 86/40; H10D 86/60; H10K 59/131

(52) U.S. Cl. CPC H10K 59/1213; H10D 86/431; H10D 86/60; H10K 59/131

(57) ABSTRACT

A display device includes an organic light-emitting diode and a first transistor arranged between a first power line and the organic light-emitting diode, the first transistor being a driving transistor. The first transistor includes a first-1 transistor controlling current flow to the organic light-emitting diode and a first-2 transistor connected in parallel to the first-1 transistor and controlling current flow to the organic light-emitting diode.

### CROSS-REFERENCE TO RELATED APPLICATION

This application is based on and claims priority, under 35 U.S.C. §119, to Korean Patent Application No. 10-2025-0030909 filed on Mar. 10, 2025 in the Korean Intellectual Property Office, the disclosure of which is incorporated by reference herein in its entirety.

### BACKGROUND

### 1. Field

The disclosure relates to a display device and an electronic device including the same.

### 2. Description of the Related Art

Among display devices, organic light-emitting display devices are attracting attention as next-generation displays because they have the advantages of a wide viewing angle, excellent contrast, and fast response speed.

An organic light-emitting display device has a thin-film transistor and an organic light-emitting diode as a display element on a substrate, and the organic light-emitting diode operates by self-emitting light. The organic light-emitting display device is used as a display unit for small products such as mobile phones, etc., and as a display unit for large products such as televisions, etc.

### SUMMARY

The disclosure provides a transistor providing improved transfer characteristics and a display device including the transistor.

According to an aspect of the disclosure, a display device includes an organic light-emitting diode and a first transistor arranged between a first power line and the organic light-emitting diode, the first transistor being a driving transistor, in which the first transistor includes a first-1 transistor controlling current flow to the organic light-emitting diode and a first-2 transistor connected in parallel to the first-1 transistor and controlling current flow to the organic light-emitting diode.

In some embodiments, the first-1 transistor may include a first gate electrode and a semiconductor layer including a first channel region overlapping the first gate electrode, the first-2 transistor may include a second gate electrode and a semiconductor layer including a second channel region overlapping the second gate electrode, and a first width of the first gate electrode in a region overlapping the semiconductor layer may be different from a second width of the second gate electrode in the region overlapping the semiconductor layer.

In some embodiments, a first length of the first gate electrode in the region overlapping the semiconductor layer may be different from a second length of the second gate electrode in the region overlapping the semiconductor layer.

In some embodiments, the first-1 transistor may further include a first gate insulation layer arranged between the first gate electrode and the semiconductor layer, the first-2 transistor may further include a second gate insulation layer arranged between the second gate electrode and the semiconductor layer, and a first thickness of the first gate insulation layer may be different from a second thickness of the second gate insulation layer.

In some embodiments, the first gate electrode and the second gate electrode may include a same material.

In some embodiments, a portion of the first gate electrode may form a portion of the second gate electrode.

In some embodiments, the first gate electrode may include a 1a-th gate electrode and a 1b-th gate electrode that is spaced apart from the 1a-th gate electrode, and the second gate electrode may be arranged between the 1a-th gate electrode and the 1b-th gate electrode.

In some embodiments, the first gate electrode and the second gate electrode may be in direct contact with each other.

In some embodiments, the first gate electrode may include a 1a-th gate electrode and a 1b-th gate electrode that are spaced apart from each other, and the second gate electrode may be arranged between the 1a-th gate electrode and the 1b-th gate electrode.

In some embodiments, a first length of the first gate electrode may be different from a first length of the second gate electrode.

According to another aspect of the disclosure, an electronic device includes a memory storing a program, a processor operating by executing the program, a display device connected to receive data from the processor and provide visual information, and a power module connected to supply power to the display device, in which the display device includes an organic light-emitting diode and a first transistor arranged between a first power line and the organic light-emitting diode, the first transistor being a driving transistor, and in which the first transistor includes a first-1 transistor controlling current flow to the organic light-emitting diode and a first-2 transistor connected in parallel to the first-1 transistor and controlling current flow to the organic light-emitting diode.

In some embodiments, the first-1 transistor may include a first gate electrode and a semiconductor layer including a first channel region overlapping the first gate electrode, the first-2 transistor may include a second gate electrode and a semiconductor layer including a second channel region overlapping the second gate electrode, and a first width of the first gate electrode in a region overlapping the semiconductor layer may be different from a second width of the second gate electrode in the region overlapping the semiconductor layer.

In some embodiments, a first length of the first gate electrode in the region overlapping the semiconductor layer may be different from a second length of the second gate electrode in the region overlapping the semiconductor layer.

In some embodiments, the first-1 transistor may further include a first gate insulation layer arranged between the first gate electrode and the semiconductor layer, the first-2 transistor may further include a second gate insulation layer arranged between the second gate electrode and the semiconductor layer, and a first thickness of the first gate insulation layer may be different from a second thickness of the second gate insulation layer.

In some embodiments, the first gate electrode and the second gate electrode may include a same material.

In some embodiments, a portion of the first gate electrode may form a portion of the second gate electrode.

In some embodiments, the first gate electrode may include a 1a-th gate electrode and a 1b-th gate electrode that is spaced apart from the 1a-th gate electrode, and the second gate electrode may be arranged between the 1a-th gate electrode and the 1b-th gate electrode.

In some embodiments, the first gate electrode and the second gate electrode may be in direct contact with each other.

In some embodiments, the first gate electrode may include a 1a-th gate electrode and a 1b-th gate electrode that are spaced apart from each other, and the second gate electrode may be arranged between the 1a-th gate electrode and the 1b-th gate electrode.

In some embodiments, a first length of the first gate electrode may be different from a first length of the second gate electrode.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a view schematically showing a display device according to an embodiment of the disclosure;

FIG. 2 is a view schematically showing wires included in the display device of FIG. 1;

FIG. 3 is a diagram showing an equivalent circuit of any one pixel of the display device of FIG. 1;

FIG. 4 is a cross-sectional view schematically showing a part of a display device according to an embodiment of the disclosure;

FIGS. 5 to 10 are plan views schematically showing some components of a thin-film transistor according to embodiments of the disclosure;

FIG. 11 is a cross-sectional view showing a cross-section taken along line I - I' of FIG. 10;

FIG. 12 is a graph schematically showing transfer characteristics of a display device according to an embodiment of the disclosure;

FIG. 13 is a block diagram of an electronic device including a display device according to embodiments of the disclosure; and

FIG. 14 shows schematic diagrams of the electronic device of FIG. 13.

### DETAILED DESCRIPTION

The disclosure may have various modifications thereto and various embodiments, and particular embodiments will be illustrated in the drawings and described in detail in a detailed description. Effects and features of the disclosure, and methods for achieving them will become clear with reference to the embodiments described later together with the drawings. However, the disclosure is not limited to the embodiments disclosed below and may be implemented in various forms.

In the following embodiments, the terms such as first, second, etc., have been used to distinguish one component from other components, rather than limiting.

In the following embodiments, singular forms include plural forms unless indicated otherwise explicitly or contextually.

In the following embodiments, the terms "include", "have", or the like, are intended to mean that there are features, or components, described herein, but do not preclude the possibility of adding one or more other features or components.

In the following embodiments, when a portion, such as a unit, a region, a component, etc., is present on or above another portion, this case may include not only a case where it is directly on the other portion, but also a case where another unit, region, component, etc., is arranged between the portion and the other portion.

In the following embodiments, terms such as connect or combine do not necessarily imply a direct and/or fixed connection or combination of two members, unless the context clearly indicates otherwise, and do not exclude the presence of another member between the two members.

In the drawings, the size of components may be exaggerated or reduced for convenience of description. For example, as the size and thickness of each component shown in the drawings are arbitrarily shown for convenience of description, the disclosure is not necessarily limited to the illustration.

Hereinafter, embodiments of the disclosure will be described in detail with reference to the attached drawings, and in the description with reference to the drawings, identical or corresponding components are given the same reference numerals and redundant descriptions thereof will be omitted.

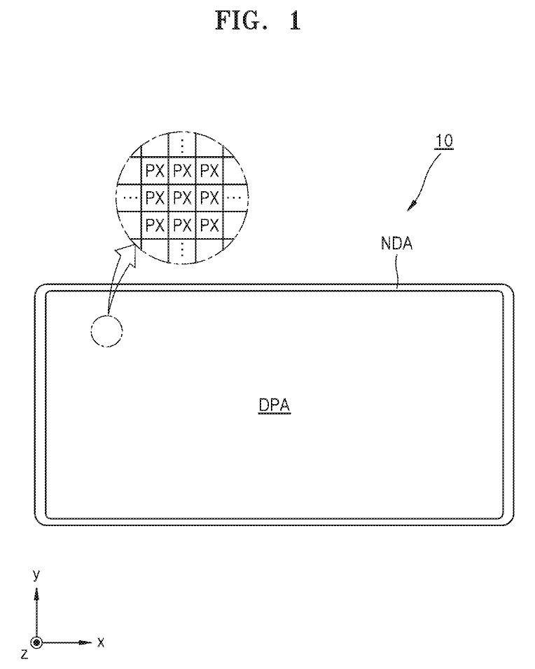

FIG. 1 is a view schematically showing a display device according to an embodiment of the disclosure.

In the following embodiments, an x-axis, a y-axis, and a z-axis are not limited to three axes on an orthogonal coordinate system, and may be interpreted in a broad sense to include the orthogonal coordinate system. In some embodiments, the x-axis, the y-axis, and the z-axis may be orthogonal to each other, but may also refer to different directions that are not orthogonal to each other. However, hereinbelow, for convenience of a description, a plane formed by the x-axis and the y-axis may be defined as being parallel to the plane on which a display device 10 is arranged, and the z-axis is defined as being in a thickness direction of the display device 10.

Referring to FIG. 1, the display device 10 according to an embodiment of the disclosure may be applied to small and medium electronic equipment such as a tablet personal computer (PC), a smart phone, a vehicle navigation unit, a camera, a center information display (CID) provided in a vehicle, a wristwatch-type electronic device, a personal digital assistant (PDA), a portable multimedia player (PMP), and a game console, or may be applied to medium-size and large-size electronic equipment such as a television, an outdoor billboard, a monitor, a PC, and a laptop computer. The display device 10 according to an embodiment of the disclosure is also applicable to various electronic devices that display images, without being limited to the foregoing examples.

The display device 10 may include a display panel providing a display screen. The display panel may be, for example, but not limited to, a liquid crystal display panel, an electrophoretic display panel, an organic light- emitting display panel, an inorganic light-emitting display panel, a field emission display panel, a plasma display panel, or a cathode ray tube display panel. However, for convenience of description, the following description will focus on an embodiment in which the display panel included in the display device 10 is an organic light-emitting display panel.

The shape of the display device 10 may be modified in various ways. For example, the display device 10 may have a shape such as a rectangle having a length greater than its width, a rectangle having a width greater than its length, a square, a rectangle with rounded corners (vertices), other polygons, a circle, etc.

The display device 10 may include a display area DPA and a non-display area NDA. The display area DPA may be an area in which a screen may be displayed, and the non-display area NDA may be an area in which no screen is displayed. The display area DPA may also be referred to as an active area, and the non-display area NDA may also be referred to as an inactive area.

The shape of the display area DPA of the display device 10 may also be similar to the overall shape of the display device 10. It is shown in FIG. 1 that the display device 10 and the display area DPA have a rectangular shape, but the shapes of the display device 10 and the display area DPA are not limited to the rectangular shape.

The non-display area NDA may be arranged around the display area DPA. The non-display area NDA may completely or partially surround the display area DPA. The display area DPA may have a rectangular shape, and the non-display area NDA may be positioned adjacent to four sides of the display area DPA. The non-display area NDA may form a bezel of the display device 10. The display area DPA may generally occupy the center of the display device 10.

In each non-display area NDA, wires or circuit driving units included in the display device 10 may be placed, or external devices may be mounted.

The display area DPA may include a plurality of pixels PX. The plurality of pixels PX may be arranged in a matrix direction. The shape of each pixel PX may be a rectangle or a square in plane, but is not limited thereto, and may also be a rhombic shape with each side inclined in a direction. Each pixel PX may be arranged alternately as a stripe type or a pentile type.

The display area DPA may provide a display screen by including the plurality of pixels PX. Specifically, each of the plurality of pixels may include one or more light-emitting elements that emit light in a specific wavelength band to display a specific color, and the display area DPA may provide a display screen using the plurality of pixels PX. For example, the pixel PX may display a specific color by emitting red, green, blue or white light through an organic light-emitting diode LD described later, and the display area DPA may provide a display screen using the plurality of pixels PX.

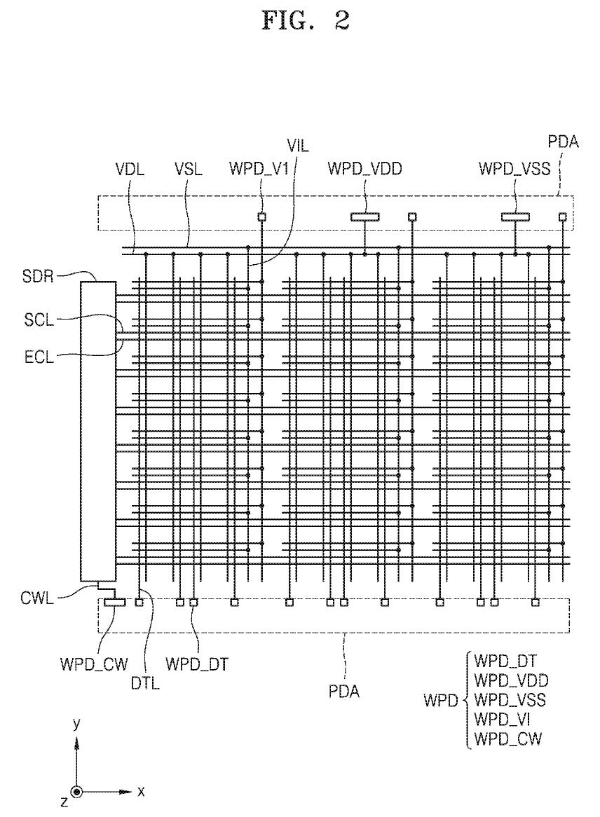

FIG. 2 is a view schematically showing wires included in the display device of FIG. 1.

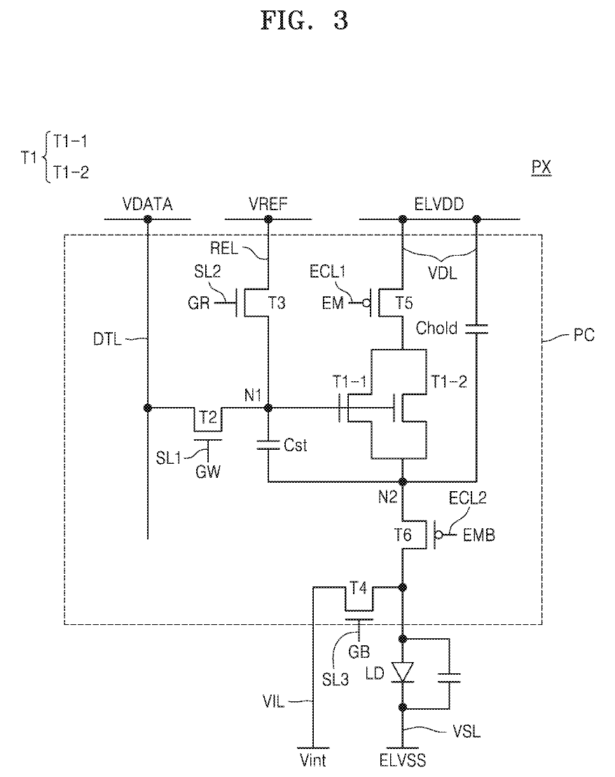

Referring to FIG. 2, the display device 10 may include a plurality of wires. The plurality of wires may include a scan signal line SL, an operation control signal line ECL, a light-emission control signal line ECL2 (see FIG. 3), a data line DTL, an initialization voltage line VIL, a first voltage line VDL, a second voltage line VSL, and so forth. Although not shown in the drawing, other wires may be further arranged on the display device 10. A schematic arrangement of the plurality of wires is merely shown in FIG. 2.

The scan signal line SCL and the operation control signal line ECL may be respectively connected to a driving unit SDR. The scan signal line SCL may be connected to a scan driving circuit included in the driving unit SDR), and the operation control signal line ECL may be connected to a light-emission signal control circuit included in the driving unit SDR.

The scan signal line SCL and the operation control signal line ECL may extend to a side. For example, each of the scan signal line SCL and the operation control signal line ECL may have a side connected to the driving unit SDR and another side extending in the x-axis direction.

The driving unit SDR may be positioned in the non-display area NDA located on a side of the display area DPA, but the disclosure is not limited thereto. In some embodiments, the driving unit SDR may be arranged in the non-display area NDA located in the x-axis direction and the -x axis direction of the display area DPA, and may include a scan driving circuit and a light-emission signal control circuit.

The driving unit SDR may be connected to a signal connection wire CWL, and at least one end of the signal connection wire CWL may form a pad WPD_CW on the non-display area NDA and thus may be connected to an external device.

The data line DTL may extend in a direction crossing a direction in which the scan signal line SCL and the operation control signal line ECL extend. The data line DTL may extend in the y-axis direction crossing the x-axis direction.

The initialization voltage line VIL may extend in a direction parallel to the data line DTL and may further include a branched portion. The initialization voltage line VIL may extend in the y-axis direction and may further include a portion branched in the x-axis direction from a portion extending in the y-axis direction.

The first voltage line VDL and the second voltage line VSL may include a portion extending in the direction in which the scan signal line SCL and the operation control signal line ECL extend, and a portion extending in a direction crossing the portion in connection to the portion. The first voltage line VDL may include a portion extending in the x-axis direction and a portion extending in the y-axis direction in connection to the portion. The first voltage line VDL and the second voltage line VSL may have a mesh structure, but the disclosure is not limited thereto.

Although not shown in the drawing, each pixel PX of the display device 10 may be connected to at least one scan line SL, the data line DTL, the operation control signal line ECL, the light-emission control signal line ECL2 (see FIG. 3), the initialization voltage line VIL, the first voltage line VDL, and the second voltage line VSL.

The data line DTL, the initialization voltage line VIL, the first voltage line VDL and the second voltage line VSL may be electrically connected to at least one wire pad WPD. Each wire pad WPD may be arranged in the non-display area NDA.

In an embodiment, a wire pad (hereinafter, referred to as a 'data pad') WPD_DT of the data line DTL may be arranged in a -y-axis direction pad area PDA of the display area DPA, and a wire pad (hereinafter, referred to as an 'initialization voltage pad') WPD_VI of the initialization voltage line VIL, a wire pad (hereinafter, referred to as a 'first power pad') WPD_VDD of the first voltage line VDL, and a wire pad (hereinafter, referred to as a 'second power pad') WPD_VSS of the second voltage line VSL may be arranged in a pad area PDA located in the y-axis direction of the display area DPA.

In another embodiment, the data pad WPD_DT, the initialization voltage pad WPD_VI, the first power pad WPD_VDD, and the second power pad WPD_VSS may all be located in the same area, for example, in the non-display area NDA located on a side of the display area DPA.

The external device may be mounted on the wire pad WPD. The external device may be mounted on the wire pad WPD via an anisotropic conductive film, ultrasonic bonding, etc.

Each pixel PX of the display device 10 may include a pixel driving circuit. The above-described wires may apply a driving signal to each pixel driving circuit while passing through each pixel PX or a periphery thereof.

The pixel driving circuit may include a transistor and a capacitor. The number of transistors and capacitors in each pixel driving circuit may be changed variously. In some embodiments, the pixel driving circuit may have a 5T2C structure including five transistors and two capacitors or a 7T1C structure including seven transistors and one capacitor. However, for convenience of a description, the following description will focus on an embodiment in which the pixel driving circuit of the display device 10 according to an embodiment of the disclosure has a 6T2C structure including six transistors and two capacitors.

FIG. 3 is a diagram showing an equivalent circuit of any one pixel of the display device of FIG. 1.

Referring to FIG. 3, each pixel PX of the display device 10 according to an embodiment of the disclosure may include a pixel circuit PC and the organic light-emitting diode LD electrically connected thereto.

The pixel circuit PC may include a plurality of transistors T1 to T6, a storage capacitor Cst, and a holding capacitor Chold, as shown in FIG. 3. The plurality of transistors T1 to T6, the storage capacitor Cst, and the holding capacitor Chold may be connected to the signal lines SL1, SL2, SL3, ECL1, ECL2, and DTL, the initialization voltage line VIL, a reference voltage line RFL, and the second voltage line VSL.

The pixel circuit PC may include the plurality of transistors T1 to T6, the storage capacitor Cst, and the holding capacitor Chold, as shown in FIG. 3. The plurality of transistors T1 to T6, the storage capacitor Cst, and the holding capacitor Chold may be connected to the signal lines SL1, SL2, ECL, and DTL, the initialization voltage line VIL, the reference voltage line RFL, the first voltage line VDL, and the second voltage line VSL.

The plurality of transistors T1 to T6 may include a first transistor T1, a second transistor T2, a third transistor T3, a fourth transistor T4, a fifth transistor T5, and a sixth transistor T6.

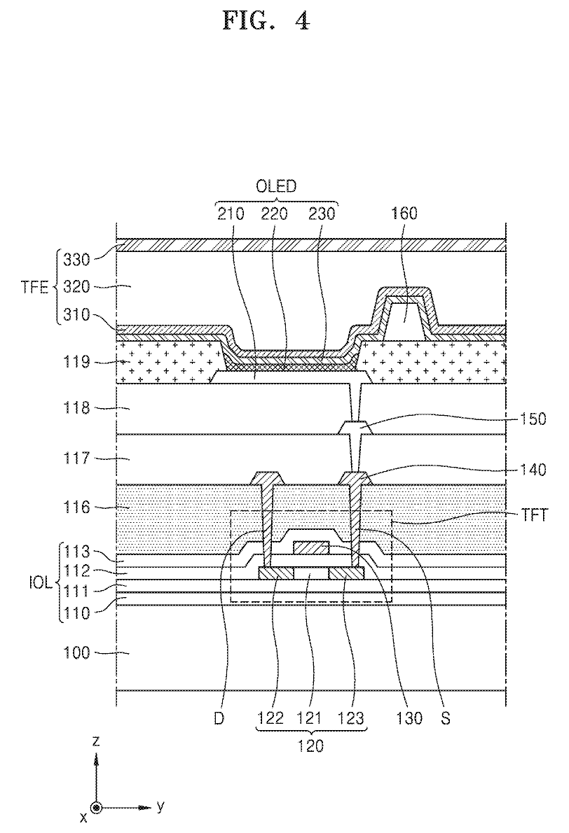

The organic light-emitting diode LD may include a pixel electrode 210 (see FIG. 4) and a counter electrode 230 (see FIG. 4). The pixel electrode 210 of the organic light-emitting diode LD may be connected to the first transistor T1 to receive a driving current, and the counter electrode 230 of the organic light-emitting diode LD may receive a second power voltage ELVSS. Thus, the organic light-emitting diode LD may generate light with a brightness corresponding to the driving current.

The signal lines may include a first scan signal line SL1 transmitting a write signal GW (a scan signal), a second scan signal line SL2 transmitting a reference voltage signal GR, a third scan signal line SL3 transmitting an initialization signal GI, the operation control signal line ECL transmitting an operation control signal EM, the light-emission control signal line ECL2 transmitting a light-emission control signal EMB, and the data line DTL crossing the first scan signal line SL1 and transmitting a data signal VDATA.

The initialization voltage line VIL may transmit an initialization voltage Vint that initializes the pixel electrode 210 of the organic light-emitting diode LD, the reference voltage line RFL may transmit a reference voltage VREF to a gate electrode of the first transistor T1, and the first voltage line VDL may transmit a first power voltage EVLDD that is a driving voltage of the first transistor T1.

The first transistor T1 may be arranged between the first voltage line VDL and the organic light-emitting diode LD. In some embodiments, a drain region of the first transistor T1 may be connected to the first voltage line VDL via the fifth transistor T5, and a source region of the first transistor T1 may be electrically connected to the pixel electrode 210 of the organic light-emitting diode LD via a second node N2. A gate electrode of the first transistor T1 may be connected to the storage capacitor Cst via a first node N1.

The first transistor T1 may be a driving transistor. The first transistor T1 may receive the data signal VDATA according to a switching operation of the second transistor T2 and supply a driving current to the organic light-emitting diode LD. The first transistor T1 may control the amount of current flowing to the organic light-emitting diode LD in response to a voltage applied to the first node N1 that changes according to the data signal VDATA.

In an embodiment, the first transistor T1 may include a first-1 transistor T1-1 and a first-2 transistor T1-2.

The first-1 transistor T1-1 and the first-2 transistor T1-2 may provide a path through which current may flow to the organic light-emitting diode LD. In some embodiments, drain regions of the first-1 transistor T1-1 and the first-2 transistor T1-2 may be connected to the first voltage line VDL via the fifth transistor T5, and source regions of the first-1 transistor T1-1 and the first-2 transistor T1-2 may be electrically connected to the pixel electrode 210 of the organic light-emitting diode LD via the second node N2. Thus, the first-1 transistor T1-1 and the first-2 transistor T1-2 may each control the current flow from the first voltage line VDL to the organic light-emitting diode LD.

The first-1 transistor T1-1 and the first-2 transistor T1-2 may be connected in parallel. The first-1 transistor T1-1 and the first-2 transistor T1-2 may be connected in parallel to each provide a path through which current transmitted from the first voltage line VDL is distributed to the first-1 transistor T1-1 and the first-2 transistor T1-2 and flows to the organic light-emitting diode LD via the second node N2.

A first current amount passing through the first-1 transistor T1-1 and a second current amount passing through the first-2 transistor T1-2 may be different from each other.

In an embodiment, a first on-resistance of the first-1 transistor T1-1 and a second on-resistance of the first-2 transistor T1-2 may be different from each other. In some embodiments, the first on-resistance of the first-1 transistor T1-1 may be greater than the second on-resistance of the first-2 transistor T1-2. Thus, in case that voltage is applied to the first transistor T1 by the first voltage line VDL, the first current amount may be less than the second current amount.

In another embodiment, a first maximum current amount that may pass through the first-1 transistor T1-1 may be different from a second maximum current amount that may pass through the first-2 transistor T1-2. In some embodiments, the first maximum current amount that may pass through the first-1 transistor T1-1 may be greater than the second maximum current amount may pass through the first-2 transistor T1-2. Even in case that the on-resistance of the first-2 transistor T1-2 is less than the on-resistance of the first-1 transistor T1-1 and thus the second current amount is greater than the first current amount, the magnitude of the second current amount may be limited to the second maximum current amount. In other words, if a voltage of at least a certain value is applied to the first-1 transistor T1-1 and the first-2 transistor T1-2, the first current amount may increase and thus may be greater than or equal to the second current amount.

Hereinafter, in case that a particular transistor ”operates as the primary transistor,” it may mean that the amount of current flowing through a particular transistor among a plurality of transistors connected in parallel is greater than the amount of current flowing through the other transistor(s), and thus the characteristics of the particular transistor are significantly reflected in a circuit.

In an embodiment, voltage ranges in which the first-1 transistor T1-1 and the first-2 transistor T1-2 primarily operate may be set differently.

In some embodiments, the first-1 transistor T1-1 may be configured to have a first on-resistance greater than a second on-resistance of the first-2 transistor T1-2 and have the first maximum current amount greater than the second maximum current amount of the first-2 transistor T1-2.

In this case, as the second current amount passing through the first-2 transistor T1-2 is greater than the first current amount within a range in which the second current amount is less than the second maximum current amount, the first-2 transistor T1-2 may operate as the primary transistor. In other words, if the voltage value applied to the first transistor T1 by the first voltage line VDL is less than a preset value, the first-2 transistor T1-2 may operate as the primary transistor.

On the other hand, if the voltage value applied to the first transistor T1 increases and the second current amount passing through the first-2 transistor T1-2 reaches the second maximum current amount, the first current amount increases, and the first current amount may be greater than or equal to the second current amount. In other words, if the voltage value applied to the first transistor T1 is equal to or exceeds a preset value, the first-1 transistor T1-1 may operate together with the first-2 transistor T1-2, or the first-1 transistor T1-1 may operate as the primary transistor.

Hereinbelow, a ”low gray-level range” may be defined as a voltage range applied to the pixel circuit PC by the first voltage line VDL such that low-brightness light is generated from the organic light-emitting diode LD, and a ”high gray-level range” may be defined as a voltage range applied to the pixel circuit PC by the first voltage line VDL such that high-brightness light is generated from the organic light-emitting diode LD.

In an embodiment, the first-1 transistor T1-1 may operate primarily in the high gray-level range, and the first-2 transistor T1-2 may operate primarily in the low gray-level range.

The first-2 transistor T1-2 may operate mainly in the low gray-level range. In some embodiments, the first-2 transistor T1-2 may be configured to have the second maximum current amount of a preset value such that the second current amount passing through the first-2 transistor T1-2 within the low gray-level range does not reach the second maximum current amount. Thus, in the low gray-level range, the second current amount greater than the first current amount passes through the first-2 transistor T1-2, causing the first-2 transistor T1-2 to primarily operate in the low gray-level range.

The first-1 transistor T1-1 may operate primarily in the high gray-level range. In some embodiments, the first-2 transistor T1-2 may have the second maximum current amount of a preset value, such that the second current amount may reach the second maximum current amount in the high gray-level range. Thus, if the voltage applied to the first transistor T1 by the first voltage line VDL rises and reaches the high gray-level range, the first current amount may be greater than the second current amount. Thus, the first-1 transistor T1-1 may operate primarily in the high gray-level range.

A first gate electrode of the first-1 transistor T1-1 and a second gate electrode of the first-2 transistor T1-2 may be connected to the same data line DTL. The first gate electrode of the first-1 transistor T1-1 and a second gate electrode 132 of the first-2 transistor T1-2 may be connected to the data line DTL via the second transistor T2 through the first node N1. As the first-1 transistor T1-1 and the first-2 transistor T1-2 receive a data signal VDAT through the first node N1, operations of the first-1 transistor T1-1 and the first-2 transistor T1-2 may be controlled simultaneously.

A specific method of setting voltage ranges in which the first-1 transistor T1-1 and the first-2 transistor T1-2 operate differently by controlling on-resistances and maximum current amounts of the first-1 transistor T1-1 and the first-2 transistor T1-2 will be described in detail later.

The gate electrode of the second transistor T2 may be connected to the first scan signal line SL1 that transmits the write signal GW, any one of the source electrode and the drain electrode of the second transistor T2 may be connected to the data line DTL, and the other of the source region and the drain region of the second transistor T2 may be connected to the gate electrode of the first transistor T1 through the first node N1.

The second transistor T2 may be a switching transistor. The second transistor T2 may transmit the data signal VDATA transmitted from the data line DTL to the first node N1 in response to a voltage applied to the first scan signal line SL1. The second transistor T2 may be turned on according to the write signal GW transmitted through the first scan signal line SL1, and may perform a switching operation to transmit the data signal VDATA transmitted to the data line DTL to the first transistor T1 through the first node N1.

The gate electrode of the third transistor T3 may be connected to the second scan signal line SL2 that transmits the reference voltage signal GR, any one of the source electrode and the drain electrode of the third transistor T3 may be connected to the reference voltage line RFL, and the other of the source electrode and the drain electrode of the third transistor T3 may be connected to the gate electrode of the first transistor T1 via the first node N1.

The third transistor T3 may transmit the reference voltage VREF from the reference voltage line RFL to the first node N1 in response to the voltage applied to the second scan signal line SL2. Sometimes, the second scan signal line SL2 may be the first scan signal line SL1 in a pixel adjacent to the pixel PX shown in FIG. 3 and included in a previous row and electrically connected to the same data line DTL. In this case, the reference voltage signal GR may be referred to as a previous writing signal (a previous scan signal).

The gate electrode of the fourth transistor T4 may be connected to the third scan signal line SL3, any one of the source region and the drain region of the fourth transistor T4 may be connected to the pixel electrode 210 of the organic light-emitting diode LD, and the other of the source region and the drain region of the fourth transistor T4 may be connected to the initialization voltage line VIL to receive the initialization voltage Vint.

The fourth transistor T4 may be turned on according to the initialization signal GI received through the third scan signal line SL3 to initialize the pixel electrode 210 of the organic light-emitting diode LD. Depending on a need, the third scan signal line SL3 may be a write signal line GWL in a pixel adjacent to the pixel PX shown in FIG. 3 and included in a next row electrically connected to the same data line DTL. In this case, the initialization signal GI may be referred to as a next writing signal (a next scan signal).

An operation control gate electrode of the fifth transistor T5 may be connected to the operation control signal line ECL, any one of the source region and the drain region of the fifth transistor T5 may be connected to the first voltage line VDL, and the other of the source region and the drain region of the fifth transistor T5 may be connected to the drain region of the first transistor T1.

As the fifth transistor T5 may be turned on according to the operation control signal EM received through the operation control signal line ECL1, the first power voltage ELVDD (the driving voltage) may be transmitted to the organic light-emitting diode LD, allowing the driving current to flow to the organic light-emitting diode LD.

The light-emission control gate electrode of the sixth transistor T6 may be connected to the light-emission control signal line ECL2, any one of the source region and the drain region of the sixth transistor T6 may be connected to the source region of the first transistor T1 via the second node N2, and the other of the source region and the drain region of the sixth transistor T6 may be connected to the pixel electrode 210 of the organic light-emitting diode LD.

As the sixth transistor T6 is turned on according to the light-emission control signal EMB received through the light-emission control signal line ECL2, the first power voltage ELVDD may be transmitted to the organic light-emitting diode LD, allowing the driving current to flow to the organic light-emitting diode LD.

FIG. 4 is a cross-sectional view schematically showing a part of a display device according to an embodiment of the disclosure.

Hereinafter, for convenience of description, a y-axis direction of FIG. 4 may be referred to as a right direction, a -y-axis direction as a left direction, a z-axis direction as an upward direction, and a -z-axis direction as a downward direction.

A barrier layer 110 may be located on the substrate 100. The barrier layer 110 may be a layer that prevents the penetration of external foreign substances, and may be a single layer or multiple layers containing inorganic substances such as silicon nitride or silicon oxide.

A buffer layer 111 may be located on the barrier layer 110. The buffer layer 111 may include an organic material or an inorganic material. Materials that may be used as the organic material may include photoresist, polyacrylic resin, polyimide resin, polyamide resin, siloxane resin, acrylic resin, epoxy resin, etc.

The buffer layer 111 may be located on the barrier layer 110 and may prevent impurities from entering various elements arranged on the substrate 100.

The thin-film transistor TFT may be positioned on the buffer layer 111. In an embodiment, the thin-film transistor TFT may include the buffer layer 111, a semiconductor layer 120, a gate insulation layer 112, and a gate electrode 130.

The thin-film transistor TFT may be the first transistor T1. As described later, the thin-film transistor TFT may be electrically connected to an organic light-emitting diode OLED to transmit current, thus driving the organic light-emitting diode OLED.

The semiconductor layer 120 may be located on the buffer layer 111. The semiconductor layer 120 may include a channel region 121 positioned on the buffer layer 111, and a source region 123 and a drain region 122 respectively connected to opposite sides of the channel region 121.

The semiconductor layer 120 may include a silicon semiconductor material. The semiconductor layer 120 may include polysilicon or amorphous silicon.

The semiconductor layer 120 may include an oxide semiconductor material. As oxide semiconductors have high carrier mobility and low leakage current, a voltage drop is not large in spite of a long operating time. Oxide semiconductors do not have a large color change of an image due to the voltage drop even in low-frequency driving, such that the oxide semiconductors may be driven at low frequencies. As the semiconductor layer 120 includes an oxide semiconductor material, a display device with low leakage current and power consumption may be implemented.

In an embodiment, the semiconductor layer 120 may be an oxide semiconductor layer including a binary compound (ABx), a ternary compound (ABxCy), a quaternary compound (ABxCyDz), etc., containing indium (In), zinc (Zn), gallium (Ga), tin (Sn), titanium (Ti), aluminum (Al), hafnium (Hf), zirconium (Zr), magnesium (Mg), etc.

In some embodiments, the semiconductor layer 120 may include, but is not limited to, zinc oxide (ZnOx), gallium oxide (GaOx), titanium oxide (TiOx), tin oxide (SnOx), indium oxide (InOx), indium-gallium oxide (IGO), indium-zinc oxide (IZO), indium-tin oxide (ITO), gallium-zinc oxide (GZO), zinc-magnesium oxide (ZMO), zinc-tin oxide (ZTO), zinc-zirconium oxide (ZnZrxOy), indium-gallium-zinc oxide (IGZO), indium-zinc-tin oxide (IZTO), indium-gallium-hafnium oxide (IGHO), tin-aluminum-zinc oxide (TAZO), indium-gallium-tin oxide (IGTO), etc.

The gate insulation layer 112 may be located on the semiconductor layer 120. The gate insulation layer 112 may be positioned between the semiconductor layer 120 and the gate electrode 130, and may electrically isolate the semiconductor layer 120 from the gate electrode 130.

The gate insulation layer 112 may include an inorganic insulation material such as silicon oxide (SiO2), silicon nitride (SiNx), or silicon oxynitride (SiOxNy), and may have a single-layer or multi-layer structure including the above-described material.

The gate electrode 130 may be located on the gate insulation layer 112. The gate electrode 130 may be positioned on the gate insulation layer 112 so as to overlap with the channel region 121 of the semiconductor layer 120.

The gate electrode 130 may include a low-resistance conductive material such as molybdenum (Mo), aluminum (Al), copper (Cu), and/or titanium (Ti), and may have a single-layer or multi-layer structure including the above-described material.

The interlayer insulation layer 113 may be positioned on the gate electrode 130. The interlayer insulation layer 113 may include an inorganic insulation material such as SiO2, SiNx, or SiOxNy, and may be a single-layer or multi-layer structure including the above-described material.

A first via insulation layer 116 may be positioned on the interlayer insulation layer 113, and a first electrode layer 140 may be positioned on the first via insulation layer 116.

In an embodiment, the first electrode layer 140 may include a source electrode S and a drain electrode D. The source electrode S may be connected to the source region 123 through a contact hole extending through the first via insulation layer 116, and the drain electrode D may be connected to the drain region 122 through a contact hole extending through the first via insulation layer 116.

The first electrode layer 140 may include Al, Mo, Ti, and/or Cu, and may be a single-layer or multi-layer structure including the above-described material. In some embodiments, the first electrode layer 140 may have a three-layer structure of titanium layer/aluminum layer/titanium layer.

A second via insulation layer 117 may be arranged on the first via insulation layer 116 and the first electrode layer 140. The second via insulation layer 117 may include an organic film such as an acrylic resin, an epoxy resin, a phenolic resin, a polyamide resin, or a polyimide resin. They may be used alone or in combination with each other.

A second electrode layer 150 may be arranged on the second via insulation layer 117. The second electrode layer 150 may be electrically connected to the first electrode layer 140 through a contact hole extending through the second via insulation layer 117. The second electrode layer 150 may include Al, Mo, Ti, and/or Cu, and may be a single-layer or multi-layer structure including the above-described material. In some embodiments, the second electrode layer 150 may have a three-layer structure of titanium layer/aluminum layer/titanium layer.

A third via insulation layer 118 may be arranged on the second via insulation layer 117 and the second electrode layer 150. The third via insulation layer 118 may include an organic film such as an acrylic resin, an epoxy resin, a phenolic resin, a polyamide resin, or a polyimide resin. They may be used alone or in combination with each other.

The organic light-emitting diode OLED may be arranged on the third via insulation layer 118. In an embodiment, the organic light-emitting diode OLED may include the pixel electrode 210, the intermediate layer 220, and the counter electrode 230.

The pixel electrode 210 may be arranged on the third via insulation layer 118. The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. The pixel electrode 210 may include a reflective film including a material described above, and a transparent conductive film arranged on and/or below the reflective film. The transparent conductive film may include ITO, IZO, zinc oxide (ZnO), indium oxide (In₂O₃ indium oxide), IGO, aluminum zinc oxide (AZO), etc. In an embodiment, the pixel electrode 210 may have a three-layer structure of ITO layer/Ag layer/ITO layer, which are sequentially stacked.

The pixel-defining film 119 may cover the edge of the pixel electrode 210 and may include an opening that exposes the center of the pixel electrode 210. The pixel-defining film 119 may include an organic insulation material such as benzocyclobutene (BCB), polyimide, hexamethyldisiloxane (HMDSO), etc. A light-emitting area may be defined by an opening in the pixel-defining film 119, and red, green, or blue light may be emitted through the light-emitting area. An area or width of the light-emitting area may define an area or width of a pixel.

A spacer 160 may be formed on the pixel-defining film 119. The spacer 160 may prevent damage to layers under the spacer 160 due to a mask during a formation process of the intermediate layer 220 described later. In an embodiment, the spacer 160 may include a material that is the same as or different from the pixel-defining film 119. In some embodiments, in case that the spacer 160 includes the same material as the pixel-defining film 119, the spacer 160 and the pixel-defining film 119 may be formed integrally through a half-tone mask.

The pixel-defining film 119 may be formed in black. This pixel-defining film 119 may include a light-blocking material and may be formed in black. The light-blocking material may include a resin or paste containing carbon black, carbon nanotubes, a black dye, a metal particle such as nickel, aluminum, molybdenum, and an alloy thereof, a metal oxide particle (e.g., chromium oxide), a metal nitride particle (e.g., chromium nitride), etc. In case that the pixel-defining film 119 includes a light-blocking material, external reflection due to metal structures arranged under the pixel-defining film 119 may be reduced.

As described above, in case that the spacer 160 includes the same material as the pixel-defining film 119, the spacer 160 and the pixel-defining film 119 may be formed integrally through a half-tone mask. Thus, in case that the pixel-defining film 119 is formed in black, the spacer 160 may also be formed in black.

The intermediate layer 220 may include a light-emitting layer overlapping the pixel electrode 210. The light-emitting layer may include an organic material. The light-emitting layer may include a high-molecular organic material or a low- molecular organic material that emits light of a selected color. The light-emitting layer may be formed through a deposition process using a mask as described above.

The counter electrode 230 may include a conductive material having a relatively low work function. In some embodiments, the counter electrode 230 may include a (semi)transparent layer including Ag, Mg, Al, Ni, Cr, Li, Ca, or an alloy thereof. The counter electrode 230 may further include a layer such as ITO, IZO, ZnO or In₂O₃ on the (semi)transparent layer including the above-described material. In an embodiment, the counter electrode 230 may include Ag and Mg.

A thin-film encapsulation layer TFE may be arranged on the organic light-emitting diode OLED and insulation layers to cover a display layer including the organic light-emitting diode OLED and the insulation layers.

In an embodiment, the thin-film encapsulation layer TFE may include a first inorganic encapsulation layer 310, an organic encapsulation layer 320, and a second inorganic encapsulation layer 330.

Each of the first inorganic encapsulation layer 310 and the second inorganic encapsulation layer 330 may include one or more inorganic insulation materials. The inorganic insulation material may include aluminum oxide, titanium oxide, tantalum oxide, hafnium oxide, zinc oxide, silicon oxide, silicon nitride, or/and silicon oxynitride. The first inorganic encapsulation layer 310 and the second inorganic encapsulation layer 330 may be formed through chemical vapor deposition.

The organic encapsulation layer 320 may include a polymer-based material. The polymer-based material may include an acrylic resin, an epoxy resin, polyimide, polyethylene, etc. In some embodiments, the organic encapsulation layer 320 may include an acrylic resin such as polymethyl methacrylate, polyacrylic acid, etc. The organic encapsulation layer 320 may be formed by curing a monomer or applying a polymer.

For convenience of a description, FIG. 4 shows one thin-film transistor TFT included in the pixel circuit PC and the organic light-emitting diode OLED electrically connected thereto, but the pixel circuit PC of the display device 10 according to an embodiment of the disclosure may further include a plurality of transistors and capacitors.

In an embodiment, the pixel circuit PC of the display device 10 may further include a plurality of thin-film transistors (not shown) positioned on the buffer layer 111. In some embodiments, the pixel circuit PC may further include the thin-film transistor TFT including the source electrode or the drain electrode electrically connected to the gate electrode 130.

In another embodiment, the pixel circuit PC of the display device 10 may further include the storage capacitor Cst including a first electrode electrically connected to the gate electrode 130 and a second electrode electrically connected to the drain region 122 of the semiconductor layer 120. The pixel circuit PC of the display device 10 may further include the hold capacitor Chold including a third electrode electrically connected to the first voltage line VDL and a fourth electrode electrically connected to the drain electrode D.

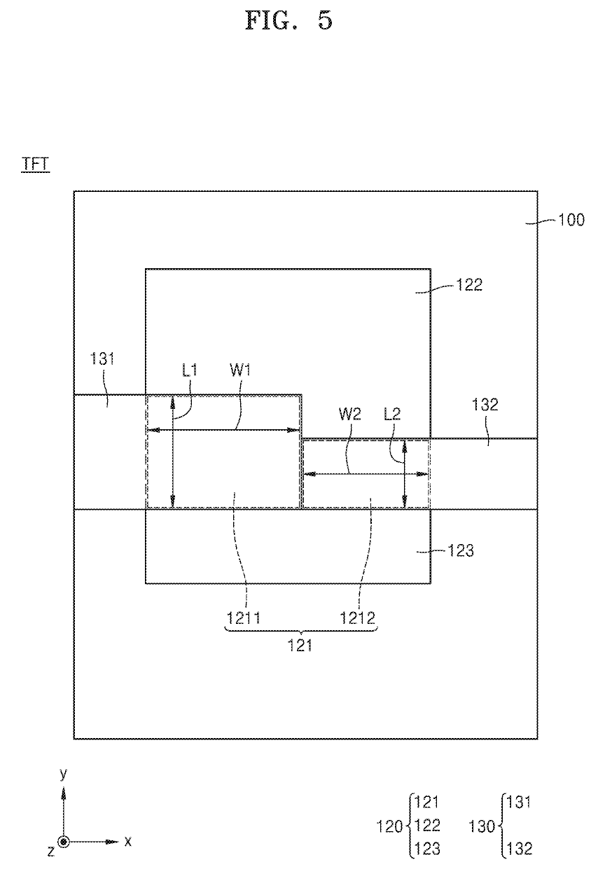

FIGS. 5 to 10 are plan views schematically showing some components of a thin-film transistor according to embodiments of the disclosure.

Hereinafter, “a layer A and a layer B include the same material” may mean that the layer A and the layer B are formed through the same process.

A “width” of the gate electrode 130 in a region overlapping the semiconductor layer 120 may mean the greater value between a linear measurement of the gate electrode 130 in one direction and a linear measurement of the gate electrode 130 in another direction perpendicular to the direction, in the region overlapping the semiconductor layer 120. A ”length” may be defined as the less value between the linear measurement of the gate electrode 130 in one direction in the region overlapping the semiconductor layer 120 and the linear measurement in another direction perpendicular to the direction, in the region overlapping the semiconductor layer 120.

Referring to FIG. 5, the thin-film transistor TFT according to an embodiment of the disclosure may include the semiconductor layer 120 positioned on the substrate 100, and the gate electrode 130 positioned on the semiconductor layer 120.

The thin-film transistor TFT according to an embodiment of the disclosure may be one of the transistors T1 to T6 of the pixel circuit PC included in the display device 10. For convenience of a description, the following description will focus on an example in which the thin-film transistor TFT is the first transistor T1.

The semiconductor layer 120 may include the channel region 121, and the source region 123 and the drain region 122 respectively connected to opposite sides of the channel region 121.

The channel region 121 may overlap the gate electrode 130 in the semiconductor layer 120. In some embodiments, the channel region 121 may include a first channel region 1211 overlapping the first gate electrode 131 and a second channel region 1212 overlapping the second gate electrode 132.

The channel region 121 may overlap the gate electrode 130 to electrically connect or separate the source region 123 to or from the drain region 122 according to a signal applied to the gate electrode 130.

The source region 123 and the drain region 122 may be arranged on opposite sides of the channel region 121 and may be electrically connected to the channel region 121.

The source region 123 and the drain region 122 may be electrically connected to other components of the pixel circuit PC. In detail, the source region 123 may receive current from the first voltage line VDL via the fifth transistor T5 through the source electrode (not shown), and the drain region 122 may transmit current to the second voltage line VSL via the sixth transistor T6 through the drain electrode (not shown).

The gate electrode 130 may be located on the semiconductor layer 120. In an embodiment, the gate electrode 130 may include the first gate electrode 131 and the second gate electrode 132.

The first gate electrode 131 and the second gate electrode 132 may include the same material. The first gate electrode 131 and the second gate electrode 132 may be located in a same layer. In some embodiments, the first gate electrode 131 and the second gate electrode 132 may be located on the gate insulation layer 112 arranged on the semiconductor layer 120.

In an embodiment, the thin-film transistor TFT may include the first-1 transistor T1-1 and the first-2 transistor T1-2.

The first-1 transistor T1-1 may include the first gate electrode 131 and the semiconductor layer 120. The first-1 transistor T1-1 may include the first gate electrode 131 and the semiconductor layer 120 including the first channel region 1211 overlapping the first gate electrode 131.

The first-2 transistor T1-2 may include the second gate electrode 132 and the semiconductor layer 120. The first-2 transistor T1-2 may include the second gate electrode 132 and the semiconductor layer 120 including the second channel region 1212 overlapping the second gate electrode 132.

The first-1 transistor T1-1 and the first-2 transistor T1-2 may share the semiconductor layer 120. Current transmitted to the source region of the semiconductor layer 120 may pass through the first channel region 1211 or the second channel region 1212 and may be transmitted to the drain region 122. Thus, the first-1 transistor T1-1 and the first-2 transistor T1-2 may be connected in parallel.

The first gate electrode 131 and the second gate electrode 132 may be directly connected to each other. As a side of the first gate electrode 131 contact a side of the second gate electrode 132, electrical connection may be formed between the first gate electrode 131 and the second gate electrode 132. An electrical signal transmitted to any one of the first gate electrode 131 or the second gate electrode 132 may also be transmitted to the other. Thus, the first-1 transistor T1-1 and the first-2 transistor T1-2 may be simultaneously controlled by a signal applied to the gate electrode 130.

The first gate electrode 131 and the second gate electrode 132 may have regions overlapping the semiconductor layer 120. A region of the first gate electrode 131 and a region of the second gate electrode 132, which overlap the semiconductor layer 120, may have various shapes such as a circle, a triangle, etc. However, for convenience of a description, the following description will focus on an example in which the regions of the first gate electrode 131 and the second gate electrode 132, which overlap the semiconductor layer 120, have a quadrilateral shape.

The first gate electrode 131 may have a first length L1 in the region overlapping the semiconductor layer 120, and the second gate electrode 132 may have a second length L2 in the region overlapping the semiconductor layer 120. The first gate electrode 131 may have the first length L1 which is an x-axis direction linear measurement in FIG. 5 of the region overlapping the semiconductor layer 120, and the second gate electrode 132 may have the second length L2 which is an x-axis direction linear measurement in FIG. 5 of the region overlapping the semiconductor layer 120.

The first length L1 may correspond to a channel length of the first-1 transistor T1-1, and the second length L2 may correspond to a channel length of the first-2 transistor T1-2.

In an embodiment, the first length L1 of the first gate electrode 131 in the region overlapping the semiconductor layer 120 and the second length L2 of the second gate electrode 132 in the region overlapping the semiconductor layer 120 may be different from each other.

In some embodiments, in case that the first length L1 is greater than the second length L2, the first current amount transmitted from the source region 123 through the first channel region 1211 to the drain region 122 may be less than the second current amount transmitted through the second channel region 1212. The first length L1 and the second length L2 may determine relative magnitudes of the first current amount and the second current amount passing through the first channel region 1211 or the second channel region 1212 (the first current amount passing through the first channel region 1211 and the second current amount passing through the second channel region 1212).

The first length L1 and the second length L2 may determine the first on-resistance of the first-1 transistor T1-1 and the second on-resistance of the first-2 transistor T1-2, respectively. In some embodiments, in case that the first length L1 is greater than the second length L2, the first current amount passing through the first-1 transistor T1-1 may be less than the second current amount passing through the first-2 transistor T1-2. Thus, the first length L1 and the second length L2 may determine a relative ratio of the first current amount and the second current amount in case that a signal is applied to the gate electrode 130.

In some embodiments, if a ratio of the first length L1 to the second length L2 exceeds a preset value, in spite of application of a signal to the gate electrode 130, current may pass through the second channel region 1212. If the ratio of the first length L1 to the second length L2 exceeds the preset value, in spite of application of a signal to the gate electrode 130, current may flow to the first-2 transistor T1-2, such that the first current amount may substantially converge to 0. Thus, in case that a signal is applied to the gate electrode 130, the first-2 transistor T1-2 may operate substantially.

The first gate electrode 131 may have a first width W1 in a region overlapping the semiconductor layer 120, and the second gate electrode 132 may have a second width W2 in a region overlapping the semiconductor layer 120. The first gate electrode 131 may have the first width W1 which is the y-axis direction linear measurement in FIG. 5 of the region overlapping the semiconductor layer 120, and the second gate electrode 132 may have the second width W2 which is the y-axis direction linear measurement in FIG. 5 of the region overlapping the semiconductor layer 120.

The first width W1 may correspond to a channel width of the first-1 transistor T1-1, and the second width W2 may correspond to a channel width of the first-2 transistor T1-2.

In an embodiment, the first width W1 of the first gate electrode 131 in the region overlapping the semiconductor layer 120 and the second width W2 of the second gate electrode 132 in the region overlapping the semiconductor layer 120 may be different from each other.

In some embodiments, if the first width W1 is greater than the second width W2, a maximum current amount that may be transmitted through the first channel region 1211 to the drain region 122 may be less than the maximum current amount that may pass through the second channel region 1212. The first width W1 and the second width W2 may determine the maximum current amount that may pass through the first channel region 1211 or the second channel region 1212 (the maximum current amount that may pass through the first channel region 1211 and the maximum current amount that may pass through the second channel region 1212), respectively.

The first width W1 and the second width W2 may determine the first maximum current amount of the first-1 transistor T1-1 and the second maximum current amount of the first-2 transistor T1-2, respectively. In some embodiments, if the first width W1 is greater than the second width W2, the first maximum current amount that may pass through the first-1 transistor T1-1 may be greater than the second maximum current amount that may pass through the first-2 transistor T1-2. Even in case that the first length L1 is greater than the second length L2 and thus the second current amount is greater than the first current amount, the second current amount may be limited to the second maximum current amount. Thus, in case that a voltage of at least a certain value is applied to the thin-film transistor TFT, the first current amount may increase and thus the first current amount may be greater than or equal to the second current amount.

In an embodiment, the respective voltage range in which the first-1 transistor T1-1 and the first-2 transistor T1-2 primarily operate may be set differently.

In some embodiments, the first length L1 of the first gate electrode 131 may be greater than the second length L2 of the second gate electrode 132, and the first width W1 of the first gate electrode 131 may be greater than the second width W2 of the second gate electrode 132.

In this case, as the second current amount passing through the first-2 transistor T1-2 is greater than the first current amount and less than the second maximum current amount, and the first-2 transistor T1-2 may operate as the primary transistor. In other words, if a voltage value applied to the thin-film transistor TFT is less than a preset value, the first-2 transistor T1-2 may operate as the primary transistor.

On the other hand, if the voltage value applied to the thin-film transistor TFT increases and thus the second current amount passing through the first-2 transistor T1-2 reaches the second maximum current amount, the first current amount may increase and become greater than or equal to the second current amount. If the voltage value applied to the thin-film transistor TFT is a preset value or greater, the first-1 transistor T1-1 may operate together with the first-2 transistor T1-2, or the first-1 transistor T1-1 may operate as the primary transistor.

In an embodiment, the first-1 transistor T1-1 may operate primarily in a high gray-level range, and the first-2 transistor T1-2 may operate primarily in a low gray-level range.

The first-2 transistor T1-2 may primarily operate in the low gray-level range. In some embodiments, the second width W2 of the second gate electrode 132 may be set such that the first-2 transistor T1-2 has the second maximum current amount of a preset value. The second width W2 may be set such that the second current amount does not reach the second maximum current amount in the low gray-level range. Thus, in the low gray-level range, the second current amount may be greater than the first current amount. That is, the first-2 transistor T1-2 may operate primarily in the low gray-level range.

The first-1 transistor T1-1 may operate primarily in the high gray-level range. In some embodiments, the second width W2 of the second gate electrode 132 may be set such that the first-2 transistor T1-2 has the second maximum current amount of a preset value and thus the second current amount reaches the second maximum current amount at a boundary between the low gray-level range and the high gray-level range. Thus, if the voltage applied to the thin-film transistor TFT increases and reaches a high gray-level range, the first current amount may be greater than the second current amount. Thus, the first-1 transistor T1-1 may operate primarily in the high gray-level range.

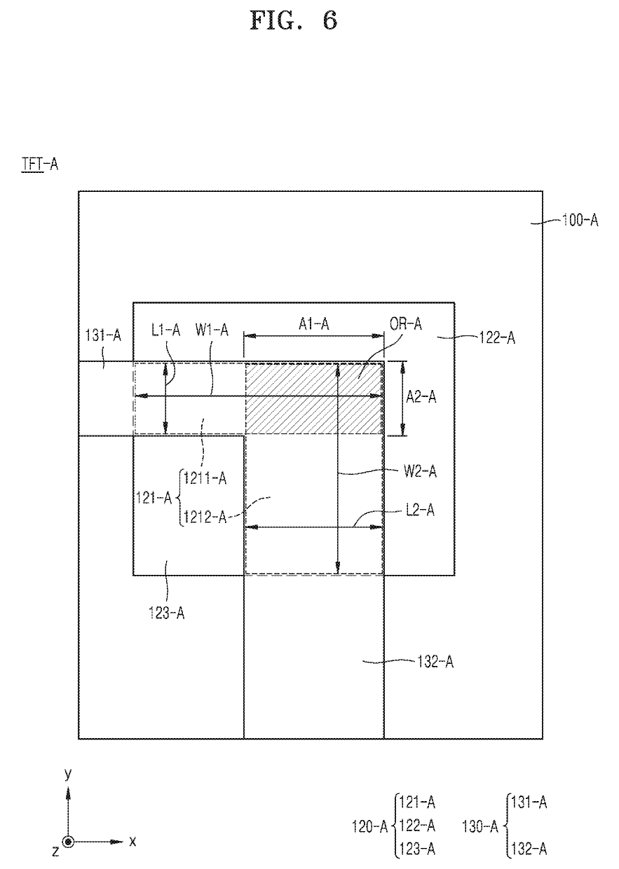

Referring to FIG. 6, as a thin-film transistor TFT-A according to another embodiment of the disclosure differs in the arrangement shape of a gate electrode 130-A in comparison to the thin-film transistor TFT according to an embodiment of the disclosure, a redundant description will be omitted and a difference will be mainly described.

A second gate electrode 132-A of the thin-film transistor TFT-A according to another embodiment of the disclosure may be arranged on a semiconductor layer 120-A so as to have a shape extending in a direction crossing a direction in which the first gate electrode 131-A extends.

In an embodiment, the first gate electrode 131-A may have a shape extending in the x-axis direction, and the second gate electrode 132-A may have a shape extending in the y-axis direction and may be arranged on the semiconductor layer 120-A. Without being limited thereto, the first gate electrode 131-A and the second gate electrode 132-A may be arranged to have a shape extending in a direction in which they cross each other at a preset angle. However, for convenience of a description, the following description will focus on an example in which the extending directions of the first gate electrode 131-A and the second gate electrode 132-A perpendicularly cross each other.

A portion of the first gate electrode 131-A may form a portion of the second gate electrode 132-A. A side of the first gate electrode 131-A connected to the second gate electrode 132-A may form a portion of the second gate electrode 132-A.

In an embodiment, the first gate electrode 131-A and the second gate electrode 132-A may be connected to form a shared region OR-A.

The shared region OR-A may be formed by connecting the first gate electrode 131-A to the second gate electrode 132-A in a direction in which they cross each other, and may have a size determined by the first gate electrode 131-A and the second gate electrode 132-A. The shared region OR-A may have a first shared length A1-A having a value equal to a second length L2-A of the second gate electrode 132-A, and may have a second shared length A2-A having a value equal to a first length L1-A of the first gate electrode 131-A.

Upon application of a signal to the first gate electrode 131-A, current may be transmitted mainly through a portion of a first channel region 1211-A overlapping the first gate electrode 131-A, excluding a channel region corresponding to the shared region OR-A. A measurement of a first width W1-A of the portion of the first gate electrode 131-A that overlaps a drain region 122-A, which substantially corresponds to a channel width of a first-1 transistor T1-1-A, may be the distance (W1-A) - (A1-A), or the first width W1-A minus the first shared length A1-A.

The measurement of the first width W1-A of the first gate electrode 131-A that determines the first maximum current amount of the first-1 transistor T1-1-A, may be the difference (W1-A) - (A1-A), or the first width W1-A minus the first shared width A1-A.

Likewise, upon application of a signal to the second gate electrode 132-A, current may be transmitted mainly through a portion of a second channel region 1212-A overlapping the second gate electrode 132-A, minus a channel region corresponding to the shared region OR-A. The length of the second width W2-A of the second gate electrode 132-A, which corresponds to the channel width of the first-2 transistor T1-2-A, may be the difference (W2-A) - (A2-A), or the second width W2-A minus the second shared length A2-A.

The length of the second width W2-A of the second gate electrode 132-A, which determines the second maximum current amount of the first-2 transistor T1-2-A, may be the difference (W2-A) - (A2-A), or the second width W2-A minus the second shared length A2-A.

In an embodiment, a length W1-A1-A of the first width W1-A of the first gate electrode 131-A, which corresponds to the channel width of the first-1 transistor T1-1-A, may be less than a distance (L2-A)-(A2-A) of the second width W2-A of the second gate electrode 132-A, which corresponds to the channel width of the first-2 transistor T1-2-A, and the first length L1-A of the first gate electrode 131-A may be less than the second length L2-A of the second gate electrode 132-A.

The first current amount may be greater than the second current amount in the low gray-level range, but the first current amount reaches the first maximum current amount at the boundary between the low gray-level range and the high gray-level range, such that in the high gray-level range, the second current amount may be greater than the first current amount. Thus, the first-1 transistor T1-1-A may operate primarily in the low gray-level range, and the first-2 transistor T1-2-A may operate primarily in the high gray-level range.

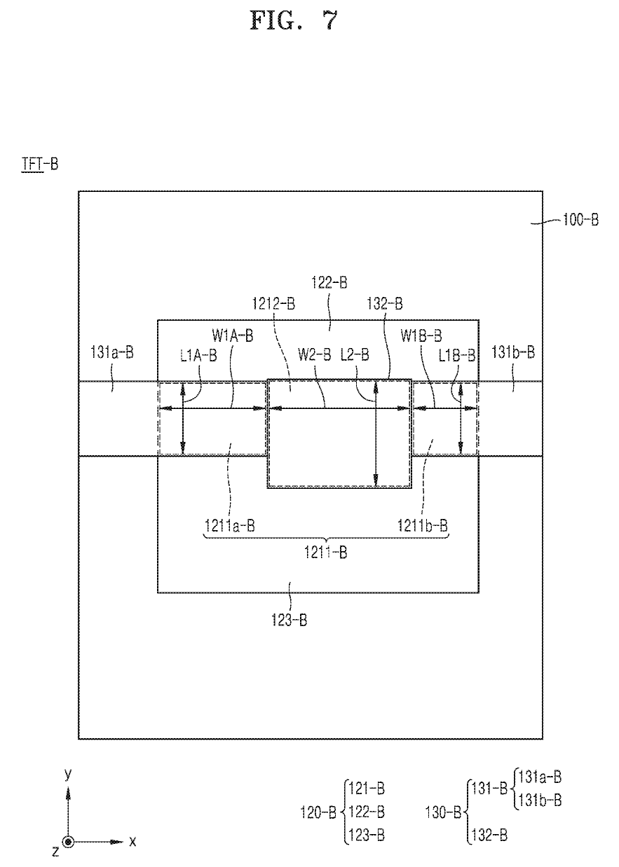

Referring to FIG. 7, a thin-film transistor TFT-B according to another embodiment of the disclosure may differ from the thin-film transistor TFT according to an embodiment of the disclosure in terms of a specific shape of a first gate electrode 131-B and an arrangement of a gate electrode 130-B, and therefore, hereinbelow, a redundant description will be omitted and a difference will be mainly described.

The thin-film transistor TFT-B according to another embodiment of the disclosure may include the first gate electrode 131-B including a 1a-th gate electrode 131a-B and a 1b-th gate electrode 131b-B that are spaced apart from each other, and a second gate electrode 132-B arranged between the 1a-th gate electrode 131a-B and the 1b-th gate electrode 131b-B.

As the second gate electrode 132-B is arranged between the 1a-th gate electrode 131a-B and the 1b-th gate electrode 131b-B. The second gate electrode 132-B and the first gate electrode 131-B may contact each other at two locations. The first gate electrode 131-B and the second gate electrode 132-B may be connected to each other at a plurality of points, such that an electrical connection between the first gate electrode 131-B and the second gate electrode 132-B may be strengthened, and a channel ratio may be maintained constant during a layer formation process.

The first-1 transistor T1-1-B may include the 1a-th gate electrode 131a-B, the 1b-th gate electrode 131b-B, and a semiconductor layer 120-B including a 1a-th channel region 1211a-B overlapping the 1a-th gate electrode 131a-B and a 1b-th channel region 1211b-B overlapping the 1b-th gate electrode 131b-B.

In an embodiment, a first width W1-B of the first gate electrode 131-B in a region overlapping with the semiconductor layer 120-B may be a combined width (W1A-B) + (W1B-B) obtained by adding a 1a-th width W1A-B of the 1a-th gate electrode 131a-B in the region overlapping the semiconductor layer 120-B and a 1b-th width W1B-B of the 1b-th gate electrode 131b-B in the region overlapping the semiconductor layer 120-B.

In another embodiment, a first length L1-B of the first gate electrode 131-B in the region overlapping with the semiconductor layer 120-B may be equal to a 1a-th length L1A-B of the 1a-th gate electrode 131a-B in the region overlapping the semiconductor layer 120-B or a 1b-th length L1B-B of the 1b-th gate electrode 131b-B in the region overlapping the semiconductor layer 120-B. The 1a-th length L1A-B and the 1b-th length L1B-B may be equal.

The first width W1-B, which is a measurement corresponding to the channel width of the first-1 transistor T1-1-B included in the thin-film transistor TFT-B according to another embodiment of the disclosure, may be the combined width (W1A-B) + (W1B-B) that is a sum of the 1a-th width W1A-B and the 1b-th width W1B-B. The first length L1-B, which is a length corresponding to the channel length of the first-1 transistor T1-1-B included in the thin-film transistor TFT-B according to another embodiment of the disclosure, may be equal to each of the 1a-th length L1A-B and the 1b-th length L1B-B.

The length, which determines the first current amount of the first-1 transistor T1-1-B with respect to the second current amount of the first-2 transistor T1-2-B, may be equal to the 1a-th length L1A-B and the 1b-th length L1B-B, and the length that determines the first maximum current amount of the first-1 transistor T1-1-B may be a length (W1A-B)+(W1B-B) that is a sum of the 1a-th width W1A-B and the 1b-th width W1B-B.

The first-2 transistor T1-2-B may include the semiconductor layer 120-B including the second gate electrode 132-B and the second channel region 1212-B overlapping the second gate electrode 132-B.

The second gate electrode 132-B may have a second width W2-B and a second length L2-B in the region overlapping with the semiconductor layer 120-B.

The channel width of the first-2 transistor T1-2-B may be the second width W2-B, and the channel length of the first-2 transistor T1-2-B may be the second length L2-B.

The length that determines the second current amount of the first-2 transistor T1-2-B with respect to the first current amount of the first-1 transistor T1-1-B, may be the second length L2-B. The width that determines the second maximum current amount of the first-2 transistor T1-2-B, may be the second width W2-B.

In an embodiment, the first width W1-B and the first length L1-B of the first gate electrode 131-B may be less than the second width W2-B and the second length L2-B of the second gate electrode 132-B, respectively. The channel width and the channel length of the first-1 transistor T1-1-B may be less than the channel width and the channel length of the first-2 transistor T1-2-B, respectively.

The first current amount may be greater than the second current amount in the low gray-level range, but the first current amount may reach the first maximum current amount at the boundary between the low gray-level range and the high gray-level range, such that the second current amount may be greater than the first current amount in the high gray-level range. Thus, the first-1 transistor T1-1-B included in the thin-film transistor TFT-B-B according to another embodiment of the disclosure may operate primarily in the low gray-level range, and the first-2 transistor T1-2-B may operate primarily in the high gray-level range.

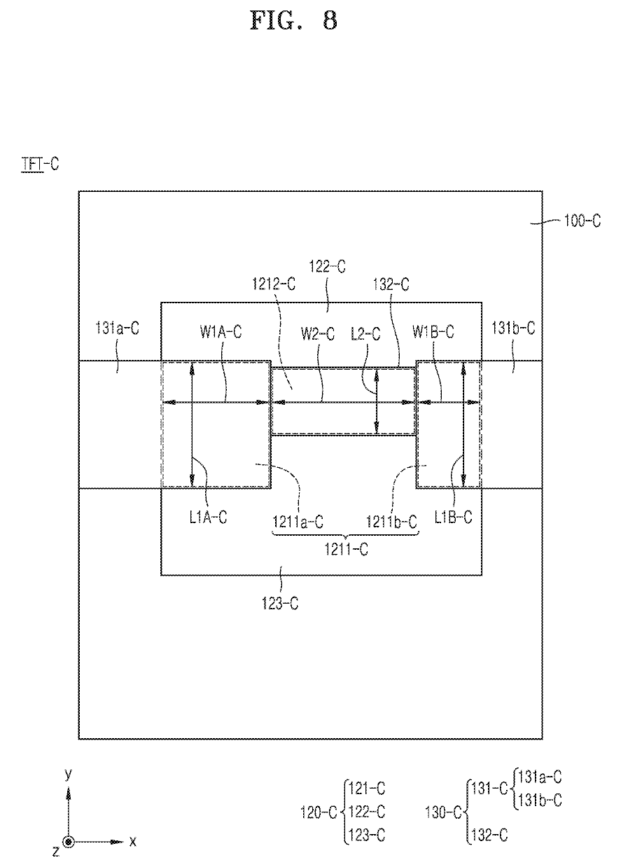

Referring to FIG. 8, a thin-film transistor TFT-C according to another embodiment of the disclosure may differ in relative sizes between a first gate electrode 131-C and a second gate electrode 132-C in comparison to the thin-film transistor TFT-B of FIG. 7, such that a redundant description will be omitted below and differences will be mainly described.

According to another embodiment of the disclosure, a first width W1-C (which may be a combination of width W1A-C and width W1B-C) and a first length L1-C (which may be either a length L1A-C or a length L1B-C) of the first gate electrode 131-C of the thin-film transistor TFT-C may be greater than a second width W2-C and a second length L2-C of the second gate electrode 132-C, respectively. The channel width and the channel length of the first-1 transistor T1-1-C may be greater than the channel width and the channel length of the first-2 transistor T1-2-C, respectively.

The second current amount may be greater than the first current amount in the low gray-level range, but the second current amount may reach the second maximum current amount at the boundary between the low gray-level range and the high gray-level range, such that the first current amount may be greater than the second current amount in the high gray-level range. Thus, the first-2 transistor T1-2-C included in the thin-film transistor TFT-C according to an embodiment of the disclosure may operate primarily in the low gray-level range, and the first-1 transistor T1-1-C may operate primarily in the high gray-level range.

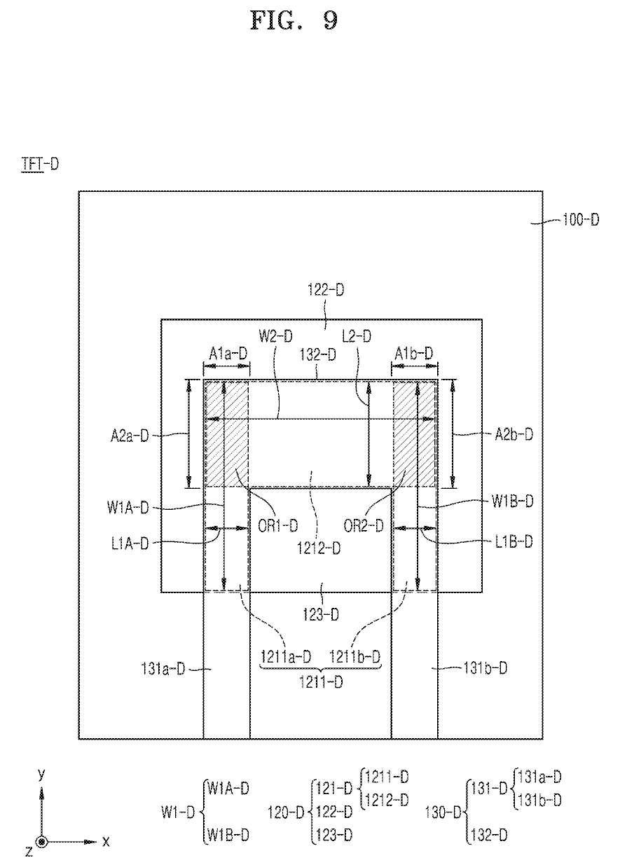

Referring to FIG. 9, a thin-film transistor TFT-D according to another embodiment of the disclosure may be different from the thin-film transistor TFT-B of FIG. 7 in an arrangement shape of a gate electrode 130-D, such that hereinbelow, a redundant description will be omitted and the description will focus on differences.

The thin-film transistor TFT-D according to another embodiment of the disclosure may include a first gate electrode 131-D including a 1a-th gate electrode 131a-D and a 1b-th gate electrode 131b-D that are spaced apart from each other, and a second gate electrode 132-D connected to the 1a-th gate electrode 131a-D and the 1b-th gate electrode 131b-D.

In an embodiment, the 1a-th gate electrode 131a-D and the 1b-th gate electrode 131b-D may have shapes extending in a direction parallel to each other and may be arranged on a semiconductor layer 120-D. In some embodiments, the 1a-th gate electrode 131a-D and the 1b-th gate electrode 131b-D may have shapes extending in the y-axis direction and may be arranged on the semiconductor layer 120-D. The 1a-th gate electrode 131a-D and the 1b-th gate electrode 131b-D may have shapes that are symmetrical to each other, and thus may have the same characteristics as components of the thin-film transistor TFT-D.

However, the disclosure is not limited to the exact arrangement depicted in FIG. 9, and the 1a-th gate electrode 131a-D and the 1b-th gate electrode 131b-D may have shapes extending in a direction crossing each other, and may be arranged on the semiconductor layer 120-D in shapes asymmetrical to each other. However, for convenience of a description, the following description will focus on an embodiment in which the 1a-th gate electrode 131a-D and the 1b-th gate electrode 131b-D are arranged on the semiconductor layer 120-D and extending in the y-axis direction parallel to each other.

The first gate electrode 131-D of the thin-film transistor TFT-D may be arranged on the semiconductor layer 120-D to have a shape extending in a direction crossing a direction in which the second gate electrode 132-D extends.

In an embodiment, the first gate electrode 131-D may have a shape extending in the y-axis direction, and the second gate electrode 132-D may have a shape extending in the x-axis direction and may be arranged on the semiconductor layer 120-D. The first gate electrode 131a-D and the first gate electrode 131b-D may extend in the y-axis direction, and the second gate electrode 132-D may have a shape extending in the x-axis direction and may be arranged on the semiconductor layer 120-D.

Without being limited thereto, the first gate electrode 131-D and the second gate electrode 132-D may be arranged to have a shape extending in a direction crossing each other at a preset angle. However, for convenience of a description, the following description will focus on an embodiment in which extending directions of the first gate electrode 131-D and the second gate electrode 132-D are perpendicular to each other.

A portion of the first gate electrode 131-D may form a portion of the second gate electrode 132-D. A side of the first gate electrode 131-D, connected to the second gate electrode 132-D, may form a portion of the second gate electrode 132-D. A side of the 1a-th gate electrode 131a-D, connected to the second gate electrode 132-D, may form a portion of the second gate electrode 132-D, and a side of the 1b gate electrode 131b-D, connected to the second gate electrode 132-D, may form a portion of the second gate electrode 132-D.

In an embodiment, the first gate electrode 131-D and the second gate electrode 132-D may be connected to form a shared region OR1-D and OR2-D (collectively referred to as OR-D). The 1a-th gate electrode 131a-D may be connected to the second gate electrode 132-D to form a first shared region OR1-D, and the 1b-th gate electrode 131b-D may be connected to the second gate electrode 132-D to form a second shared region OR2-D.

The shared region OR-D may be formed by connecting the first gate electrode 131-D to the second gate electrode 132-D in a crossing direction, and may have a size determined by the first gate electrode 131-D and the second gate electrode 132-D.

In some embodiments, the first shared region OR1-D may have a 1a-th shared length A1a-D having the same value as a 1a-th length L1A-D of a 1a-th gate electrode 131a-D and a 2a-th shared length A2a-D having the same value as a second length L2-D of the second gate electrode 132. The second shared region OR2-D may have a 1b-th shared length A1b-D having the same value as a 1b-th length L1B-D of a 1b-th gate electrode 131b-D and a 2b-th shared length A2b-D having the same value as the second length L2-D of the second gate electrode 132-D.

If a signal is applied to the first gate electrode 131-D, current may be transmitted mainly through a portion of the first channel region 1211-D, which overlaps the first gate electrode 131-D excluding the channel region corresponding to the shared region OR-D. The channel width of a first-1 transistor T1-1-D, may be the difference (W1A-D) - (A2a-D) excluding the 2a-th shared length A2a-D from a 1a-th width W1A-D or the difference (W1B-D)-(A2b-D) excluding the 1b-th shared length A2b-D from a 1b-th width W1B-D.

Likewise, in case that a signal is applied to the second gate electrode 132-D, current may be transmitted mainly through a portion of the second channel region 1212-D, which overlaps the second gate electrode 132-D excluding the channel region corresponding to the shared region OR-D. A second width W2-D of the second gate electrode 132-D, which substantially corresponds to a channel width of a first-2 transistor T1-2-D, may be the difference (W2-D) - (A1a-D) - (A1b-D) excluding the 1a-th shared length A1a-D and the 1b-th shared length A1b-D from the second width W2-D.

In an embodiment, the difference (W1A-D) – (A2a-D) which corresponds to the channel width of the first-1 transistor T1-1-D, may be less than the difference (W2-D) - (A1a-D) - (A1b-D), which corresponds to the channel width of the first-2 transistor T1-2-D. The first length L1-D of the first gate electrode 131-D may be less than the second length L2-D of the second gate electrode 132-D. The first width W1-D may be the same as the width W1A-D or W1B-D.

In the thin-film transistor TFT-D according to another embodiment of the disclosure, the first current amount may be greater than the second current amount in the low gray-level range, but the first current amount may reach the first maximum current amount at the boundary between the low gray-level range and the high-gray-level range, such that the second current amount may be greater than the first current amount in the high-gray-level range. Thus, the first-1 transistor T1-1-D may operate primarily in the low gray-level range, and the first-2 transistor T1-2-D may operate primarily in the high gray-level range.

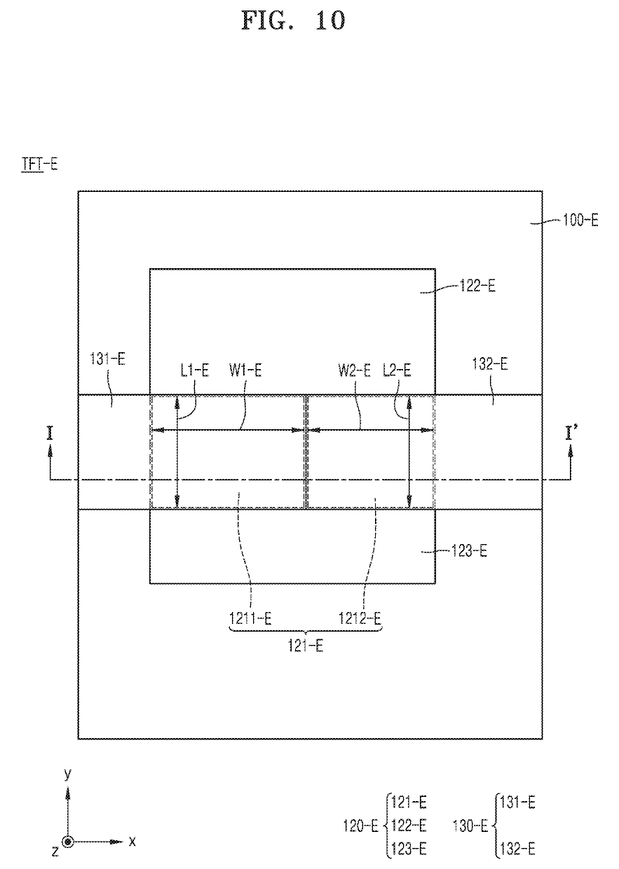

Referring to FIG. 10, a thin-film transistor TFT-E according to another embodiment of the disclosure differs in terms of relative sizes of a first gate electrode 131-E and a second gate electrode 132-E in comparison to the thin-film transistor TFT according to an embodiment of the disclosure, and therefore, hereinbelow, a redundant description will be omitted and the description will focus on the differences.

In an embodiment, a first length L1-E of the first gate electrode 131-E and a second length L2-E of the second gate electrode 132-E may be equal to each other. A length corresponding to a channel length of the first-1 transistor T1-1-E and a length corresponding to a channel length of the first-2 transistor T1-2-E may be equal to each other.

In another embodiment, a first width W1-E of the first gate electrode 131-E and a second width W2-E of the second gate electrode 132-E may be different from each other. The first width W1-E of the first gate electrode 131-E may be greater than the second width W2-E of the second gate electrode 132-E. The first maximum current amount of the first-1 transistor T1-1-E may be greater than the second maximum current amount of the first-2 transistor T1-2-E.

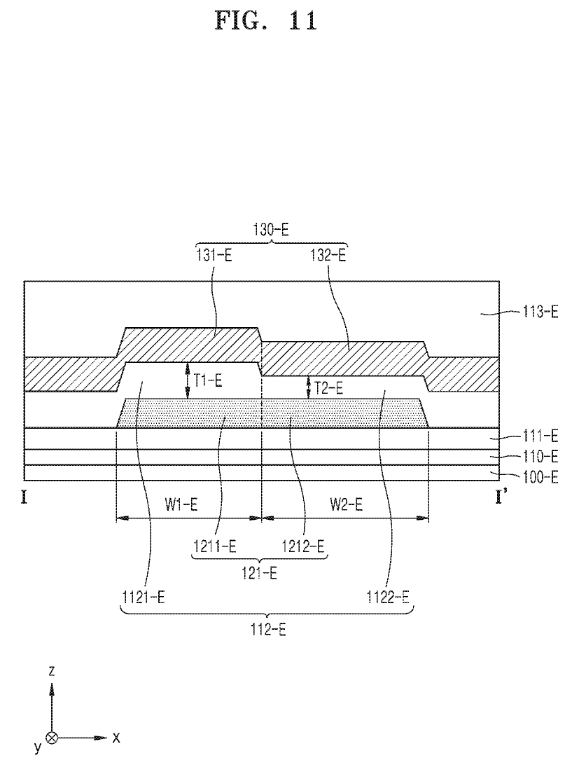

FIG. 11 is a cross-sectional view showing a cross-section taken along line I - I' of FIG. 10.

Referring to FIG. 11, the thin-film transistor TFT-E according to another embodiment of the disclosure may include a gate insulation layer 112-E arranged between a gate electrode 130-E and a channel region 121-E.

The thin-film transistor TFT-E may further include a first gate insulation layer 1121-E between the first gate electrode 131-E and the channel region 1211-E and a second gate insulation layer 1122-E between the second gate electrode 132-E and the channel region 1212-E.

The first-1 transistor T1-1-E may further include the first gate insulation layer 1121-E between the first gate electrode 131-E and the channel region 1211-E. The first-2 transistor T1-2-E may further include the second gate insulation layer 1122-E between the second gate electrode 132-E and the channel region 1212-E.

In an embodiment, the first gate insulation layer 1121-E and the second gate insulation layer 1122-E may include a same material. The first gate insulation layer 1121-E and the second gate insulation layer 1122-E may be located in a same layer. In some embodiments, both the first gate insulation layer 1121-E and the second gate insulation layer 1122-E may be positioned on the channel region 121-E. The first gate insulation layer 1121-E and the second gate insulation layer 1122-E may be formed through the same process, but may be formed with different thicknesses using a half-tone mask. The disclosure is not limited thereto, and the first gate insulation layer 1121-E and the second gate insulation layer 1122-E may be formed of different insulation layers.

In an embodiment, a first thickness T1-E of the first gate insulation layer 1121-E and a second thickness T2-E of the second gate insulation layer 1122-E may be different from each other.

In some embodiments, in case that the first thickness T1-E of the first gate insulation layer 1121-E is greater than the second thickness T2-E of the second gate insulation layer 1122-E, upon application of a signal to the gate electrode 130-E, the first current amount passing through a first channel region 1211-E may be less than the second amount of current passing through a second channel region 1212-E. If the first thickness T1-E of the first gate insulation layer 1121-E is greater than the second thickness T2-E of the second gate insulation layer 1122-E, in spite of application of a signal to the gate electrode 130-E, the first current amount of the first-1 transistor T1-1-E may be less than the second current amount of the first-2 transistor T1-2-E. Thus, the first thickness T1-E and the second thickness T2-E may determine a ratio of the first current amount to the second current amount upon application of a signal to the gate electrode 130-E.

In an embodiment, a voltage range in which the first-1 transistor T1-1-E and the first-2 transistor T1-2-E primarily operate may be set differently.

In some embodiments, the first thickness T1-E of the first gate insulation layer 1121-E may be greater than the second thickness T2-E of the second gate insulation layer 1122-E, and the first width W1-E of the first gate electrode 131-E may be greater than the second width W2-E of the second gate electrode 132-E.

As the second current amount passing through the first-2 transistor T1-2-E is greater than the first current amount within a range in which the second current amount is less than the second maximum current amount, the first-2 transistor T1-2-E may operate as the primary transistor. If a voltage value applied to the thin-film transistor TFT-E is a preset value or less, the first-2 transistor T1-2-E may operate as the primary transistor.

In case that the voltage value applied to the thin-film transistor TFT-E increases and the second current amount passing through the first-2 transistor T1-2-E reaches the second maximum current amount, the second current amount may not increase, but the first current amount may increase and thus may be greater than the second current amount. If the voltage value applied to the thin-film transistor TFT-E is a preset value or more, the first transistor T1-1-E may operate as the primary transistor.

The second width W2-E of the second gate electrode 132-E may be set such that the second current amount may reach the second maximum current amount at the boundary between the low gray-level range and the high-gray-level range. If the voltage value applied to the thin-film transistor TFT-E increases from the boundary between the low gray-level range and the high-gray-level range, the first current amount increases and thus may be greater than the second current amount. Thus, the first-1 transistor T1-1-E may operate primarily in the high gray-level range, and the first-2 transistor T1-2-E may operate primarily in the low gray-level range.

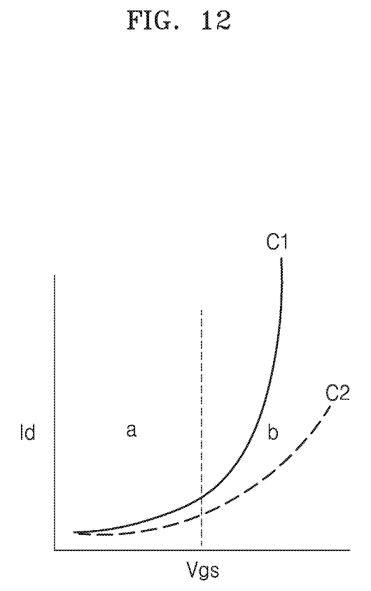

FIG. 12 is a graph schematically showing transfer characteristics of display devices according to an embodiment of the disclosure and a comparative embodiment. The display device according to the comparative embodiment may include a thin-film transistor including a gate electrode having one length L and one width W on an insulation layer of a same thickness, unlike the embodiments of the disclosure.

The transfer characteristics may correspond to a change in drain current Ids with respect to a gate voltage Vgs.

In the graph of FIG. 12, a region a may represent a region where a voltage less than that of a region b is applied to a thin-film transistor. In some embodiments, the region a may represent the low gray-level range, and the region b may represent the high-gray-level range. A first transfer curve C1 may represent the transfer characteristics of the thin-film transistor according to embodiments of the disclosure, and a second transfer curve C2 may represent the transfer characteristics of the thin-film transistor according to the comparative embodiment.

Referring to FIG. 12, unlike the second transfer curve C2 which has a constant slope change in the regions a and b, the first transfer curve C1 may have different characteristics in the regions a and b. A slope of the first transfer curve C1 in the region b may be greater than a slope in the region a. The slope of the first transfer curve C1 may change significantly upon entry from the region a to the region b.

In an embodiment, the first transfer curve C1 may represent different transistor characteristics in the region a and the region b.

In the thin-film transistor TFT according to an embodiment of the disclosure, a transistor primarily operating in the region a may be the first-2 transistor T1-2. The first transfer curve C1 may represent the characteristics of the first-2 transistor T1-2 in the region a.

In the thin-film transistor TFT according to an embodiment of the disclosure, the transistor that primarily operates in the region b may be the first-1 transistor T1-1. The second current amount of the first-2 transistor T1-2 may reach the second maximum current amount in the high gray-level range, such that the first current amount passing through the first-2 transistor T1-2 may increase. The first transfer curve C1 may represent the characteristics of the first-1 transistor T1-1 in the region b.

The thin-film transistor TFT according to an embodiment of the disclosure may set a primarily operating transistor in each preset voltage range differently, thereby providing different transfer characteristics for each voltage range. Thus, the thin-film transistor TFT according to an embodiment of the disclosure may have improved transfer characteristics.

The thin-film transistor TFT according to an embodiment of the disclosure may control current more precisely in case that a signal is applied to the gate. The thin-film transistor TFT according to an embodiment of the disclosure may include a plurality of parallel-connected transistors, and operate in different ways depending on an applied voltage, thereby enabling more precise control of the drain current. That is, the thin-film transistor TFT according to an embodiment of the disclosure may have improved transfer characteristics as different transistors operate in low gray-level ranges and high gray-level ranges.

The display device 10 according to an embodiment may be applied to various electronic devices. The electronic device according to an embodiment may include the display device 10 described above, and may further include a module or device having additional functions in addition to the display device 10.

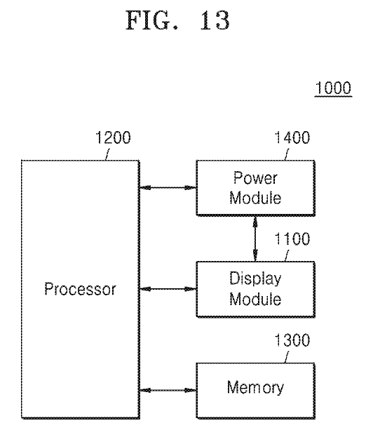

FIG. 13 is a block diagram of an electronic device including a display device according to embodiments of the disclosure.

Referring to FIG. 13, an electronic device 1000 according to an embodiment may include a display module 1100, a processor 1200, a memory 1300, and a power module 1400.

The processor 1200 may include at least one of a central processing unit (CPU), an application processor AP, a graphic processing unit (GPU), a communication processor (CP), an image signal processor (ISP), and a controller.

The memory 1300 may store data information necessary for the operation of the processor 1200 or the display module 1100. When the processor 1200 executes an application stored in the memory 1300, an image data signal and/or an input control signal may be transmitted to the display module 1100, and the display module 1100 may process the received signal and output the image information through a display screen.

The power module 1400 may include a power supply module, such as a power adapter, a battery device, etc., and a power conversion module that converts power supplied by the power supply module to generate power required for the operation of the electronic device 1000.

At least one of the components of the electronic device 1100 may be included in the display device according to the above-described embodiments. Some of individual modules functionally included in a module may be included in the display device and others may be provided separately from the display device. In some embodiments, the display device may include the display module 1100, and the processor 1200, the memory 1300, and the power module 1400 may be provided in the form of other devices in the electronic device 1100 other than the display device.

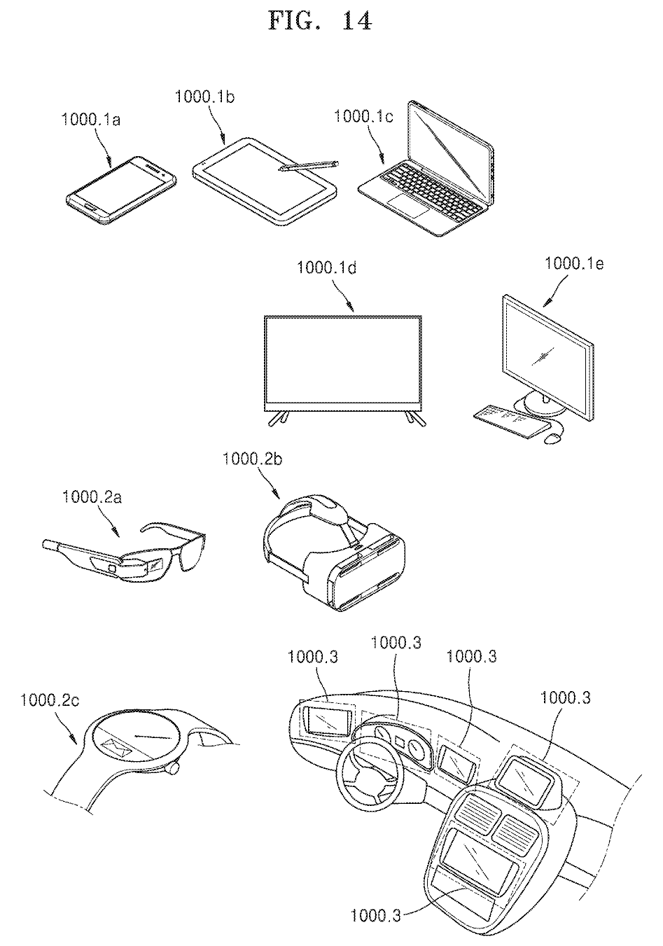

FIG. 14 shows schematic diagrams of the electronic device of FIG. 13.

Referring to FIG. 14, various electronic devices to which the display device according to embodiments is applied may include not only image display electronic devices such as a smart phone 1000.1a, a tablet PC 1000.1b, a laptop computer 1000.1c, a TV 1000.1d, a desk monitor 1000.1e, etc., but also wearable electronic devices including display modules such as smart glasses 1000.2a, a head mounted display 1000.2b, a smart watch 1000.2c, etc., and vehicle electronic devices 1000.3 including display modules such as an instrument panel, a center fascia, a center information display (CID) arranged on a dashboard, a room mirror display, etc., of vehicles.

A display device according to embodiments of the disclosure may include a first organic insulation layer having a first thickness, a second organic insulation layer having a second thickness, and a third organic insulation layer having a third thickness on a first conductive layer, and by causing a sum of the first thickness to the third thickness to be a preset thickness, a position of a stress neutral plane (NP) may be adjusted to protect a first conductive layer without applying a bending protection layer.

A thin-film transistor according to an embodiment of the disclosure may control current more precisely upon application of a signal to the gate. A thin-film transistor according to an embodiment of the disclosure may include a plurality of parallel-connected transistors, and may use a different transistor operating according to an applied voltage, thereby enabling more precise control of the drain current.

Each of the embodiments described above may be implemented independently, but it goes without saying that a structure of each embodiment may also be applied in combination to other embodiments.

Although the disclosure has been described with reference to an embodiment shown in the drawings, it will be understood by those of ordinary skill in the art that various modifications and equivalent other embodiments may also be made therefrom. Accordingly, the true technical scope of the disclosure should be defined by the technical spirit of the appended claims.

Specific implementations described in the embodiments are examples and do not limit the scope of the embodiments in any way. In addition, when there is no specific mentioning, such as "essential" or "important", it may not be a necessary component for the application of the disclosure.

In the specification (especially, claims) of the disclosure, the use of the term "the" and similar indicators thereof may correspond to both the singular and the plural. In addition, in case that the range is described in the embodiments, the range includes the disclosure to which an individual value falling within the range is applied (unless stated otherwise), and is the same as the description of an individual value constituting the range in the description of the disclosure. Finally, where there is no apparent description of the order of operations constituting the method according to the disclosure or a contrary description thereof, the operations may be performed in any appropriate order. The disclosure is not necessarily limited according to the describing order of the operations. The use of all examples or exemplary terms in the disclosure are to simply describe the disclosure in detail, and unless the range of the disclosure is not limited by the examples or the exemplary terms unless limited by the claims. It may be understood by those of ordinary skill in the art that various modifications, combinations, and changes may be made according to design conditions and factors within the scope of the appended claims or equivalents thereof.

However, the effects of the disclosure are not limited to the foregoing effects, and may be expanded in various ways without departing from the spirit and scope of the disclosure.

What is claimed is:

1. A display device comprising:
an organic light-emitting diode; and
a first transistor arranged between a first power line and the organic light-emitting diode, the first transistor being a driving transistor,
wherein the first transistor comprises:
a first-1 transistor controlling current flow to the organic light-emitting diode; and
a first-2 transistor connected in parallel to the first-1 transistor and controlling current flow to the organic light-emitting diode.

2. The display device of claim 1, wherein the first-1 transistor comprises a first gate electrode and a semiconductor layer comprising a first channel region overlapping the first gate electrode,
the first-2 transistor comprises a second gate electrode and a semiconductor layer comprising a second channel region overlapping the second gate electrode, and
a first width of the first gate electrode in a region overlapping the semiconductor layer is different from a second width of the second gate electrode in a region overlapping the semiconductor layer.

3. The display device of claim 2, wherein a first length of the first gate electrode in the region overlapping the semiconductor layer is different from a second length of the second gate electrode in the region overlapping the semiconductor layer.

4. The display device of claim 2, wherein the first-1 transistor further comprises a first gate insulation layer arranged between the first gate electrode and the semiconductor layer,
the first-2 transistor further comprises a second gate insulation layer arranged between the second gate electrode and the semiconductor layer, and
a first thickness of the first gate insulation layer is different from a second thickness of the second gate insulation layer.

5. The display device of claim 2, wherein the first gate electrode and the second gate electrode comprise a same material.

6. The display device of claim 2, wherein a portion of the first gate electrode forms a portion of the second gate electrode.

7. The display device of claim 2, wherein the first gate electrode comprises a 1a-th gate electrode and a 1b-th gate electrode that is spaced apart from the 1a-th gate electrode, and
the second gate electrode is arranged between the 1a-th gate electrode and the 1b-th gate electrode.

8. The display device of claim 2, wherein the first gate electrode and the second gate electrode are in direct contact with each other.

9. The display device of claim 2, wherein the first gate electrode comprises a 1a-th gate electrode and a 1b-th gate electrode that are spaced apart from each other, and
the second gate electrode is arranged between the 1a-th gate electrode and the 1b-th gate electrode.

10. The display device of claim 9, wherein a first length of the first gate electrode is different from a first length of the second gate electrode.

11. An electronic device comprising:
a memory storing a program;
a processor operating by executing the program;
a display device connected to receive data from the processor and provide visual information; and
a power module connected to supply power to the display device,
wherein the display device comprises:
an organic light-emitting diode; and
a first transistor arranged between a first power line and the organic light-emitting diode, the first transistor being a driving transistor, and
wherein the first transistor comprises:
a first-1 transistor controlling current flow to the organic light-emitting diode; and
a first-2 transistor connected in parallel to the first-1 transistor and controlling current flow to the organic light-emitting diode.

12. The electronic device of claim 11, wherein the first-1 transistor comprises a first gate electrode and a semiconductor layer comprising a first channel region overlapping the first gate electrode,
the first-2 transistor comprises a second gate electrode and a semiconductor layer comprising a second channel region overlapping the second gate electrode, and
a first width of the first gate electrode in a region overlapping the semiconductor layer is different from a second width of the second gate electrode in a region overlapping the semiconductor layer.

13. The electronic device of claim 12, wherein a first length of the first gate electrode in the region overlapping the semiconductor layer is different from a second length of the second gate electrode in the region overlapping the semiconductor layer.

14. The electronic device of claim 12, wherein the first-1 transistor further comprises a first gate insulation layer arranged between the first gate electrode and the semiconductor layer,
the first-2 transistor further comprises a second gate insulation layer arranged between the second gate electrode and the semiconductor layer, and
a first thickness of the first gate insulation layer is different from a second thickness of the second gate insulation layer.

15. The electronic device of claim 12, wherein the first gate electrode and the second gate electrode comprise a same material.

16. The electronic device of claim 12, wherein a portion of the first gate electrode forms a portion of the second gate electrode.

17. The electronic device of claim 12, wherein the first gate electrode comprises a 1a-th gate electrode and a 1b-th gate electrode that is spaced apart from the 1a-th gate electrode, and
the second gate electrode is arranged between the 1a-th gate electrode and the 1b-th gate electrode.

18. The electronic device of claim 12, wherein the first gate electrode and the second gate electrode are in direct contact with each other.

19. The electronic device of claim 12, wherein the first gate electrode comprises a 1a-th gate electrode and a 1b-th gate electrode that are spaced apart from each other, and
the second gate electrode is arranged between the 1a-th gate electrode and the 1b-th gate electrode.

20. The electronic device of claim 19, wherein a first length of the first gate electrode is different from a first length of the second gate electrode.
